(19) United States
(12) Patent Application Publication
(10) Pub. No.: US 2026/0219589 A1
(43) Pub. Date: Jul. 30, 2026

(54) THERMAL CONDITIONING SYSTEM AND LITHOGRAPHIC APPARATUS

(71) Applicant: ASML NETHERLANDS B.V., Veldhoven (NL)

(72) Inventors: Zhuangxiong HUANG, Eindhoven (NL); Frank Pieter Albert VAN DEN BERKMORTEL, Deurne (NL); Niek Jacobus Johannes ROSET, Eindhoven (NL); Joris Wilhelmus Henricus VERMUNT, Eindhoven (NL); Gijs KRAMER, Nijmegen (NL); Marcus Martinus Petrus Adrianus VERMEULEN, Leende (NL)

(73) Assignee: ASML NETHERLANDS B.V., Veldhoven (NL)

(21) Appl. No.: 19/145,525

(22) PCT Filed: Dec. 12, 2023
(86) PCT No.: PCT/EP2023/085253

§ 371 Date: Jul. 3, 2025

(30) Foreign Application Priority Data
Jan. 12, 2023 (EP) 23151426.6

(51) Int. Cl. G03F 7/00

(52) U.S. Cl. CPC G03F 7/70875; G03F 7/70891; G03F 7/70991

(57) ABSTRACT

A thermal conditioning system for a lithographic apparatus, the thermal conditioning system including: a body having a conditioning channel for flow of a conditioning fluid for thermally conditioning the body and/or a component supported by or supporting the body; and a supply connection configured to supply the conditioning fluid to the conditioning channel of the body, the supply connection shaped such that the conditioning fluid enters the body in a first direction and flows into the conditioning channel in a second direction different from the first direction, wherein the body has a chamber adjacent to the supply connection in the first direction and configured to at least reduce a force applied by the supply connection to the body.

### CROSS-REFERENCE TO RELATED APPLICATIONS

This application claims priority of EP Application Serial No. 23151426.6 which was filed on 12 January 2023, and which is incorporated herein in its entirety by reference.

### FIELD

The present invention relates to a thermal conditioning system, a lithographic apparatus including a thermal conditioning system, a method of thermal conditioning, and a method of manufacturing a device including a method of thermal conditioning.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Some wavelengths in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus. The immersion fluid may be confined to a localized area between the projection system of the lithographic apparatus and the substrate by a fluid handling structure.

Further improvements in the resolution of smaller features may be achieved by employing EUV radiation for the projection beam. The lithographic apparatus may comprise EUV reflectors that reflect the beam.

### SUMMARY

In a semiconductor manufacturing process, one or more bodies of the lithographic apparatus may be thermally conditioned, so as to control the temperature of the body or a component supported by the body or a component supporting the body. For example, a substrate may be supported on a substrate support which may be thermally conditioned. As another example, a reflector such as an EUV reflector may by thermally conditioned.

The thermal conditioning fluid may apply a force on the body when it enters the body. This force may undesirably affect the shape and/or position of a surface of a thermally conditioned component. For example, the thermal conditioning fluid entering a substrate support a substrate may undesirably affect the flatness of the substrate.

It is an object of the present invention to reduce the effect of the force on a body caused by thermal conditioning fluid entering that body.

According to the present invention, there is provided a thermal conditioning system for a lithographic apparatus, the thermal conditioning system comprising:
a body comprising a conditioning channel for flow of a conditioning fluid for thermally conditioning the body and/or a component supported by or supporting the body; and
a supply connection configured to supply the conditioning fluid to the conditioning channel of the body, the supply connection shaped such that the conditioning fluid enters the body in a first direction and flows into the conditioning channel in a second direction different from the first direction, wherein:
the body comprises a chamber adjacent to the supply connection in the first direction and configured to at least reduce a force applied by the supply connection to the body.

According to the present invention, there is also provided a lithographic apparatus including a thermal conditioning system.

According to the present invention, there is also provided a method of thermal conditioning, the method comprising:
entering a conditioning fluid into a body through a supply connection in a first direction;
flowing the conditioning fluid through the supply connection and into a conditioning channel of the body in a second direction different from the first direction, thereby supplying the conditioning fluid to the conditioning channel of the body; and
flowing the conditioning fluid through the conditioning channel of the body so as to thermally condition the body and/or a component supported by or supporting the body;
wherein a force applied by the supply connection to the body is at least reduced by a chamber of the body adjacent to the supply connection in the first direction.

According to the present invention, there is also provided a method of manufacturing a device including a method of thermal conditioning.

Further embodiments, features and advantages of the present invention, as well as the structure and operation of the various embodiments, features and advantages of the present invention are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 schematically depicts a schematic overview of a lithographic apparatus;

FIG. 2 schematically depicts a cross-sectional view of a radially outer section of a substrate support;

FIG. 3 schematically depicts a reflector of a lithographic apparatus;

FIG. 4 schematically depicts a cross-sectional view of a supply connection for a body of a lithographic apparatus; and

FIG. 5 schematically depicts a cross-sectional view of another supply connection for a body of a lithographic apparatus.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

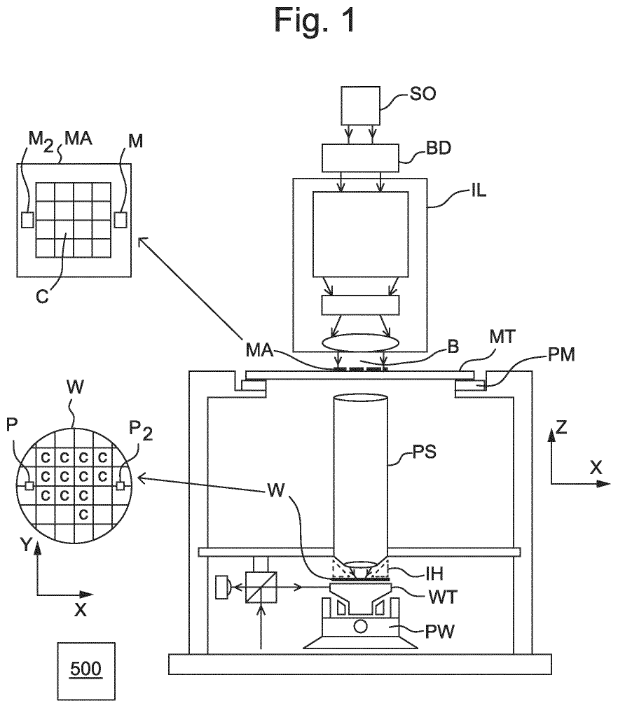

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross-section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

In an embodiment, the lithographic apparatus is of a type wherein at least a portion of the substrate W may be covered by an immersion liquid having a relatively high refractive index, e.g., water, so as to fill an immersion space between the projection system PS and the substrate W-which is also referred to as immersion lithography. More information on immersion techniques is given in U.S. Pat. No. 6,952,253, which is incorporated herein by reference. In an alternative embodiment, the lithographic apparatus is of a type employing EUV radiation.

The lithographic apparatus may be of a type having two or more substrate supports WT (also named “dual stage”). In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space between the final element and a surface facing the final element. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). When the lithographic apparatus is of a type employing immersion lithography, a fluid handling structure IH present between the projection system PS and the substrate support WT is used to confine the immersion liquid to the immersion space. The immersion space filled by the immersion liquid is smaller in plan than the top surface of the substrate W and the immersion space remains substantially stationary relative to the projection system PS while the substrate W and substrate support WT move underneath.

In FIG. 1, the fluid handling structure IH is shown in broken lines because when the lithographic apparatus is of a type employing EUV radiation, the fluid handling structure IH may not be included in the lithographic apparatus. When the lithographic apparatus is of a type employing EUV radiation, a radiation source may be configured to generate an EUV radiation beam and to supply the EUV radiation beam to the lithographic apparatus. The EUV radiation beam is incident upon a patterning device. As a result of interaction with the patterning device, a patterned EUV radiation beam is generated and projected onto the substrate.

Other immersion systems have been envisaged such as an unconfined immersion system (a so-called ‘All Wet’ immersion system) and a bath immersion system. In an unconfined immersion system, the immersion liquid covers more than the surface under the final element. The liquid outside the immersion space is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure IH is a structure which supplies the immersion liquid to the immersion space, removes the immersion liquid from the immersion space and thereby confines the immersion liquid to the immersion space. It includes features which are a part of a fluid supply system. The arrangement disclosed in PCT patent application publication no. WO 99/49504 is an early fluid handling structure comprising pipes which either supply or recover the immersion liquid from the immersion space and which operate depending on the relative motion of the stage beneath the projection system PS. In more recent designs, the fluid handling structure IH extends along at least a part of a boundary of the immersion space between the final element of the projection system PS and the substrate support WT or substrate W, so as to in part define the immersion space.

Immersion liquid may be used as the immersion fluid. In that case the fluid handling structure IH may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure IH between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element is at least partly surrounded by the fluid handling structure IH. The fluid handling structure IH may confine the immersion liquid under the final element and above the facing surface.

As depicted in FIG. 1, the lithographic apparatus comprises a controller 500. The controller 500 is configured to control the substrate support WT.

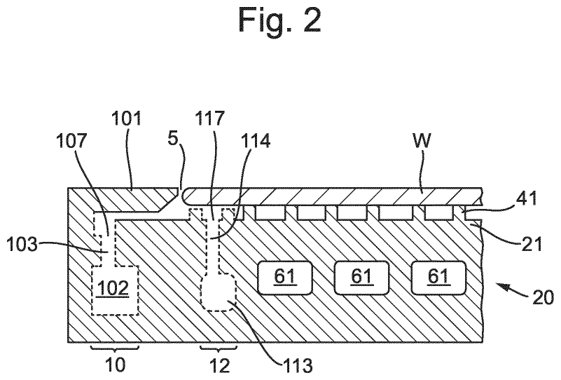

FIG. 2 illustrates part of a lithographic apparatus that is useful for demonstrating features of the present invention. The arrangement illustrated in FIG. 2 and described below may be applied to the lithographic apparatus described above and illustrated in FIG. 1. FIG. 2 is a cross-section through a substrate support 20 and a substrate W. In an embodiment, the substrate support 20 comprises one or more conditioning channels 61 of a thermal conditioner, which is described in more detail below. A gap 5 exists between an edge of the substrate W and an edge of the substrate support 20. When the edge of the substrate W is being imaged or at other times such as when the substrate W first moves under the projection system PS (as described above), any immersion space filled with liquid by the fluid handling structure IH (for example) will pass at least partly over the gap 5 between the edge of the substrate W and the edge of the substrate support 20. This can result in liquid from the immersion space entering the gap 5.

The substrate W is held by a support body 21 (e.g. a pimple or burl table) comprising one or more burls 41 (i.e., projections from the surface). The support body 21 is an example of an object holder. Another example of an object holder is a mask support. An under-pressure applied between the substrate W and the substrate support 20 helps ensure that the substrate W is held firmly in place. However, if immersion liquid gets between the substrate W and the support body 21 this can lead to difficulties, particularly when unloading the substrate W.

In order to deal with the immersion liquid entering that gap 5 at least one drain 10, 12 is provided at the edge of the substrate W to remove immersion liquid which enters the gap 5. In the embodiment of FIG. 2 two drains 10, 12 are illustrated though there may only be one drain or there could be more than two drains. In an embodiment, each of the drains 10, 12 is annular so that the whole periphery of the substrate W is surrounded. In FIG. 2, the two drains 10, 12 are shown in broken lines because when the lithographic apparatus is of a type employing EUV radiation, the two drains 10, 12 may not be included in the lithographic apparatus.

A primary function of the first drain 10 (which is radially outward of the edge of the substrate W/support body 21) is to help prevent bubbles of gas from entering the immersion space where the liquid of the fluid handling structure IH is present. Such bubbles may deleteriously affect the imaging of the substrate W. The first drain 10 is present to help avoid gas in the gap 5 escaping into the immersion space in the fluid handling structure IH. If gas does escape into the immersion space, this can lead to a bubble which floats within the immersion space. Such a bubble, if in the path of the projection beam, may lead to an imaging error. The first drain 10 is configured to remove gas from the gap 5 between the edge of the substrate W and the edge of the recess in the substrate support 20 in which the substrate W is placed. The edge of the recess in the substrate support 20 may be defined by a cover ring 101 which is optionally separate from the support body 21 of the substrate support 20. The cover ring 101 may be shaped, in plan, as a ring and surrounds the outer edge of the substrate W. The first drain 10 extracts mostly gas and only a small amount of immersion liquid.

The second drain 12 (which is radially inward of the edge of the substrate W/support body 21) is provided to help prevent liquid which finds its way from the gap 5 to underneath the substrate W from preventing efficient release of the substrate W from the substrate table WT after imaging. The provision of the second drain 12 reduces or eliminates any problems which may occur due to liquid finding its way underneath the substrate W.

As depicted in FIG. 2, in an embodiment the lithographic apparatus comprises a first extraction channel 102 for the passage therethrough of a two phase flow. The first extraction channel 102 is formed within a block. The first and second drains 10, 12 are each provided with a respective opening 107, 117 and a respective extraction channel 102, 113. The extraction channel 102, 113 is in fluid communication with the respective opening 107, 117 through a respective passageway 103, 114.

In FIG. 2, the two seals around the opening 117 are shown in broken lines because when the lithographic apparatus is of a type employing EUV radiation, the two seals may not be included in the lithographic apparatus.

As depicted in FIG. 2, the cover ring 101 has an upper surface. The upper surface extends circumferentially around the substrate W on the support body 21. In use of the lithographic apparatus, the substrate support 20 moves relative to the fluid handling structure IH. During this relative movement, the fluid handling structure IH moves across the gap 5 between the cover ring 101 and the substrate W. In an embodiment the relative movement is caused by the substrate support 20 moving under the fluid handling structure IH. In an alternative embodiment the relative movement is caused by the fluid handling structure IH moving over the substrate support 20. In a further alternative embodiment the relative movement is provided by movement of both the substrate support 20 under the fluid handling structure IH and movement of the fluid handling structure IH over the substrate support 20.

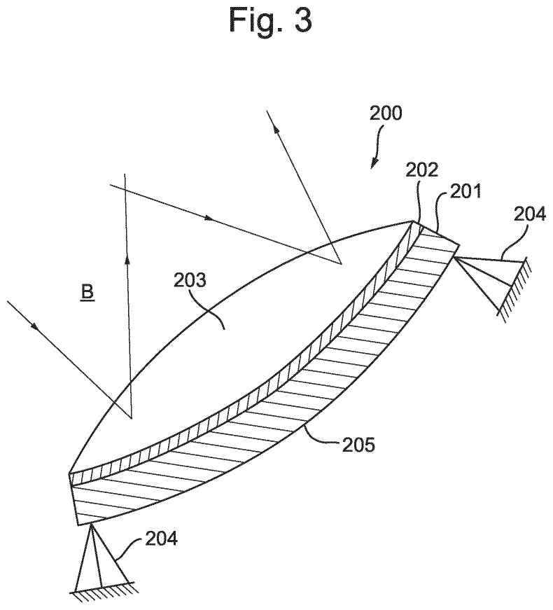

FIG. 3 schematically depicts a reflector of a lithographic apparatus. The arrangement illustrated in FIG. 3 and described below may be applied to the lithographic apparatus described above and illustrated in FIG. 1.

FIG. 3 depicts in partial cross-section a reflector that can be used in a reflective or catadioptric optical system of a lithography apparatus, for example the illumination system IL or the projection system PS. A reflective optical system is useful in lithography apparatus employing EUV radiation for the projection beam B. Reflector 200 comprises a reflector substrate 201 formed of a material having a high stiffness and a low co-efficient of thermal expansion, e.g. Zerodur™ or ULE™. A multilayer coating 202 is provided on the reflector substrate 201 and takes the form of a distributed Bragg reflector in order to reflect near normal incident EUV radiation. The reflective surface 203 of multilayer coating 202 forms a primary surface of the reflector 200 as deformations of the reflective surface 203 affect the pattern projected onto the substrate W. In particular, changes in the overall orientation of reflective surface 203 will change the position of the pattern projected onto the substrate. Local variations in the angle of reflective surface 203 will distort the pattern projected onto the substrate W. Small expansions or contractions of reflector substrate 200 may not have a significant effect on the projected pattern unless they result in changes to the orientation or surface contour of the reflective surface 203. Reflector 200 can be mounted on active mounts 204 which are controlled to maintain the desired orientation of the reflective surface 203.

In spite of the use of a multilayer coating 202, the reflectivity of an EUV reflector is only of the order of 70%. Therefore, an EUV reflector experiences a substantial heat load during use and active cooling thereof is desirable. Similarly to the substrate support 20 of FIG. 2, in an embodiment the reflector substrate 201 comprises one or more conditioning channels 61 of a thermal conditioner. The conditioning channels 61 may have a complex path within reflector substrate 201 in order to ensure that all parts of the reflector 200 are adequately conditioned. Local deformation of the rear surface 205 and overall growth of the reflector substrate 201 may not significantly affect the projected pattern.

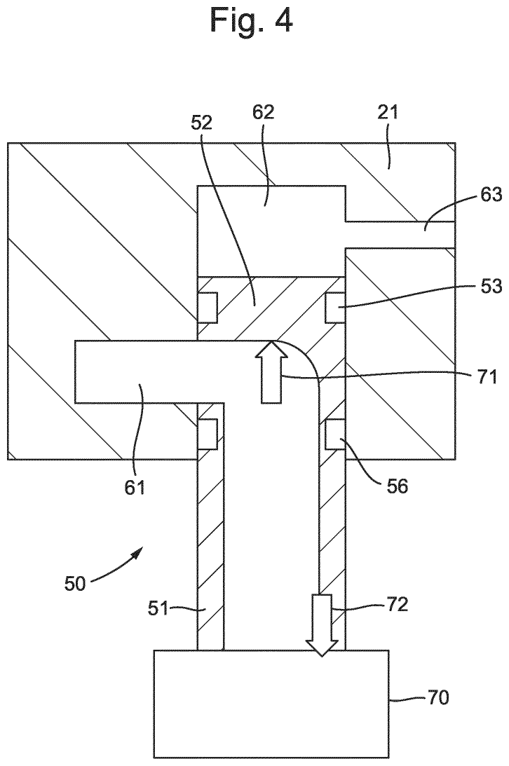

FIG. 4 schematically depicts a cross-sectional view of a supply connection 50 for a body of a component of a lithographic apparatus. The arrangement illustrated in FIG. 4 and described below may be applied to the lithographic apparatus described above and illustrated in FIG. 1. In FIG. 4, the body to which the supply connection 50 is applied is a support body 21 of a substrate support 20. The support body 21 may be of the type shown in FIG. 2, for example. The supply connection 50 and its application to the body is described below in the context of the body being such a support body 21. The supply connection 50 may additionally or alternatively be applied to one or more other bodies of a lithographic apparatus such as the reflector 200 shown in FIG. 3, for example.

FIG. 4 schematically depicts a cross-sectional view of a thermal conditioning system. The thermal conditioning system is for a lithographic apparatus such as the lithographic apparatus shown in FIG. 1. As shown in FIG. 4, in an embodiment the thermal conditioning system comprises a body such as the support body 21. In an embodiment the support body 21 comprises at least one conditioning channel 61. The conditioning channel 61 is for flow of a conditioning fluid. In an embodiment the conditioning fluid is for thermally conditioning the support body 21. The conditioning channel 61 is connected to the supply connection 50 in the support body 21. Additionally or alternatively, in an embodiment the conditioning fluid is for thermally conditioning a component supported by the support body 21. For example, the support body 21 may support a substrate W. The conditioning fluid may be for thermally conditioning the substrate W. Additionally or alternatively, in an embodiment the conditioning fluid is for thermally conditioning a component that supports the body.

The conditioning fluid may be a liquid such as water, for example. Alternatively the conditioning fluid may be a gas. The conditioning fluid flows through the conditioning channel 61 and exchanges heat with the support body 21. In an embodiment the controller 500 is configured to control the temperature of the conditioning fluid so as to control the temperature of the support body 21 and/or the substrate W. The conditioning fluid may be used to remove heat from the support body 21 or to provide heat to the support body 21. The thermal conditioning system allows the temperature of the support body 21 and the substrate W to be controlled. This helps to control the shape of the surface of the substrate W, for example to improve its flatness. When the body is a reflector 200, then the thermal conditioning system may improve the flatness or other intended shape of the surface of the reflector 200.

As shown in FIG. 4, in an embodiment the thermal conditioning system comprises a supply connection 50. The supply connection 50 is configured to supply the conditioning fluid to the conditioning channel 61 of the support body 21. The supply connection 50 is configured for the flow of the conditioning fluid into the conditioning channel 61.

As shown in FIG. 4, in an embodiment the supply connection 50 is configured to receive conditioning fluid from a fluid manifold 70. The fluid manifold 70 may comprise one or more conduits, e.g. pipes for supplying conditioning fluid to the thermal conditioning system. The supply connection 50 may be arranged between the fluid manifold 70 and the conditioning channel 61 in the circuit of the conditioning fluid.

As shown in FIG. 4, in an embodiment the supply connection 50 is shaped such that the conditioning fluid enters the support body 21 in a first direction. In the orientation of the drawing shown in FIG. 4, the first direction is vertically upwards. However, it is not essential for the first direction to be vertical. The first direction (i.e. the angle of the conduit of the supply connection 50) may be different from that shown in FIG. 4.

As shown in FIG. 4, in an embodiment the supply connection 50 is shaped such that the conditioning fluid flows into the conditioning channel 61 in a second direction. The second direction is different from the first direction. In the orientation of the drawing shown in FIG. 4, the second direction is horizontally from right to left. However, it is not essential for the second direction to be horizontal. The second direction (i.e. the angle of the conditioning channel 61) may be different from that shown in FIG. 4.

As shown in FIG. 4, in an embodiment the support body 21 comprises a chamber 62. The chamber 62 is adjacent to the supply connection 50. In an embodiment the chamber 62 is adjacent to the supply connection 50 in the first direction. In the arrangement shown in FIG. 4, the first direction is vertical. The chamber 62 is adjacent to the supply connection 50 vertically. The chamber 62 is above the supply connection 50. In an alternative embodiment the first direction is different from vertical in which case the chamber 62 may not be directly above the supply connection 50.

When the conditioning fluid flows into the support body 21 via the supply connection 50, the conditioning fluid applies a force on the support body 21. The force may be applied in the first direction, i.e. the direction in which the conditioning fluid enters the support body 21. The force may undesirably affect the shape and/or position of the support body 21 and/or the substrate W. For example the force may undesirably reduce the flatness of the surface of the substrate W that faces away from the support body 21. In an embodiment the chamber 62 is configured to dampen the force. The chamber 62 may be a buffer chamber configured to act as a buffer.

In an embodiment the chamber 62 is configured to reduce a force applied by the supply connection 50 to the support body 21. The chamber 62 may be configured as a mechanical/dynamic buffer to isolate/dampen any disturbance in the first direction due to conditioning fluid pressure propagating through the supply connection 50. In an embodiment the gas in the chamber 62 is compressed when the force due to the conditioning fluid is applied. An embodiment of the invention is expected to reduce undesirable effects of any force on the body imposed by the entry of the conditioning fluid. This may help to improve the accuracy with which the shape and/or position of the support body 21 and/or the substrate W can be controlled. For example, in the context of a reflector 200, by reducing pressure fluctuation any negative impact on the reflector line-of-sight and eventually overlay penalty may be reduced.

As shown in FIG. 4, in an embodiment the support body 21 is substantially plate shaped. The support body 21 may have a plate shape. The plate shape may be in a plane. For example, the support body 21 as depicted in FIG. 4 has a plate shape in a plane that extends horizontally and into-and-out from the page. When the body is a reflector 200, for example as shown in FIG. 3, for example, the plate shape may be angled relative to the horizontal. The surface of the reflector 200 may not be perfectly flat, but may be substantially flat.

As shown in FIG. 4, in an embodiment an angle between the second direction and a plane parallel to the plate shape is less than an angle between the second direction and a normal to the plane. In the arrangement shown in FIG. 4, the second direction is horizontal and the plate shape extends horizontally. The angle between the second direction and a plane parallel to the plate shape is substantially zero. In an alternative embodiment the angle between the second direction and a plane parallel to the plate shape is non-zero. For example, in an embodiment the angle between the second direction and a plane parallel to the plate shape is at most 20°, optionally at most 10°, optionally at most 5°, optionally at most 2°, and optionally at most 1°. A smaller angle may allow the conditioning fluid to thermally condition the support body 21 more uniformly across the support body 21.

In the arrangement shown in FIG. 4, the second direction is horizontal and the normal to the plane parallel to the plate shape is vertical. The angle between the second direction and the normal is substantially a right angle, i.e., 90°. In an alternative embodiment the angle between the second direction and a normal to a plane parallel to the plate shape is less than 90°. For example, in an embodiment the angle between the second direction and a normal to a plane parallel to the plate shape is at least 45°, optionally at least 70°, optionally at least 80°, optionally at least 85°, and optionally at least 88°. A smaller angle may reduce the lateral space taken up by the supply connection 50.

In the arrangement shown in FIG. 4, the conditioning fluid exits the supply connection 50 (enters the internal conditioning channel 61 of the support body 21) in a horizontal direction. In an embodiment the supply connection 50 is configured such that the flow line of the conditioning fluid inside the supply connection follows a substantially “L” shape. As shown in FIG. 4, in an embodiment the tip of the supply connection 50 is closed. The conditioning fluid pressure acts on the first end portion 52 (also known as the inner body top) of the supply connection 50 (instead of acting on the support body 21) in the first direction.

As shown in FIG. 4, in an embodiment the chamber 62 is directly adjacent to the first end portion 52 of the supply connection 50. The gas inside the chamber 62 comes into contact with the first end portion 52. Alternatively, the chamber 62 may be indirectly adjacent to the supply connection 50. For example a thin section of the support body 21 may be between the chamber 62 and the supply connection 50. The section is thin enough that the chamber 62 compresses when the conditioning fluid that enters the support body 21 applies a force in the first direction.

As shown in FIG. 4, in an embodiment the supply connection 50 is shaped such that the conditioning fluid flowing substantially straight through the supply connection 50 so as to enter the support body 21 along the first direction encounters an inner surface of the supply connection 50. By encountering the inner surface, the conditioning fluid applies a force. This force is indicated by the force arrow 71 shown in FIG. 4. This force may be reduced, e.g. dampened, by the chamber 62.

As shown in FIG. 4, in an embodiment the supply connection 50 comprises a conduit portion 51. The conditioning fluid flows through the conduit portion 51. The conduit portion 51 may have a longitudinal direction which may define the general flow direction of conditioning fluid entering the support body 21. The conduit portion 51 may be shaped such that the conditioning fluid flows in a direction that is substantially straight when it enters the support body 21. Of course there may be some turbulence in the flow of the conditioning fluid. In an embodiment the supply connection 50 may be slightly bent/curved.

As shown in FIG. 4, in an embodiment the supply connection 50 comprises a conduit portion 51 formed as a pipe. An embodiment of the invention is expected to provide a simple design of the supply connection 50. This may improve the reliability of the supply connection 50 and/or reduce the cost of manufacturing the supply connection 50.

As shown in FIG. 4, in an embodiment the supply connection 50 is secured to the fluid manifold 70. In an embodiment the supply connection 50 is fixed to the fluid manifold 70, for example by a bayonet lock. However, it is not essential for the supply connection 50 to be secured directly to the fluid manifold 70. The conditioning fluid pressure acting on the first end portion 52 of the supply connection 50 may be at least partly balanced by a force from the connection between the supply connection 50 and the fluid manifold 70 (or between the supply connection 50 and another external body). Such a force is shown by the force arrow 72 in FIG. 4. Such a force may counteract any reaction force when fluid pressure is applied due to conditioning fluid entering the supply connection 50. Such a force may be in the fixing, e.g. screws, between the conduit portion 51 and the fluid manifold 70. An embodiment of the invention is expected to at least reduce, and optionally eliminate, force in the first direction due to conditioning fluid pressure acting on the support body 21. In an alternative embodiment the connection between the conduit portion 51 and the fluid manifold 70 is substantially forceless. There is substantially no reaction force when fluid pressure is applied due to conditioning fluid entering the supply connection 50.

As shown in FIG. 4, in an embodiment the chamber 62 is fluidly connectable to an environment external to the support body 21. As shown in FIG. 4, in an embodiment a vent passage 63 (or venting channel/hole) is provided for fluidly connecting the chamber 62 to the ambient environment. The support body 21 may comprise a vent passage 63 configured to fluidly connect the chamber 62 to an environment external to the support body 21. The vent passage 63 may be permanently open. Alternatively, the vent passage 63 may be controllably opened and closed, e.g., by a valve. In an embodiment the connection between the supply connection 50 and the support body 21 is substantially forceless. There is substantially no reaction force when fluid pressure is applied by conditioning fluid entering the support body 21. The connection between the chamber 62 and the ambient environment reduces or eliminates any pressure difference between the two ends of the supply connection 50.

An embodiment of the invention is expected to improve isolation/damping performance of the chamber 62. By connecting the chamber 62 with the ambient environment, gas may exit the chamber 62 and enter the ambient environment when the chamber 62 is compressed. This reduces the possibility of the chamber 62 functioning like a spring mechanically coupling the support body 21 with the supply connection 50.

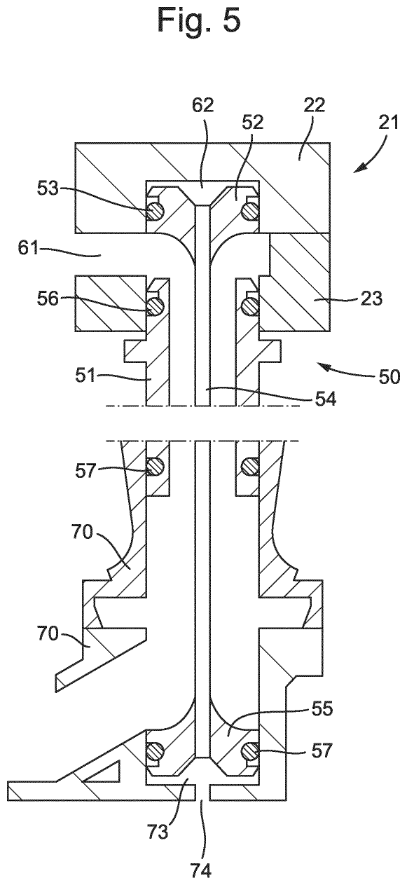

As shown in FIG. 4, in an embodiment the vent passage 63 may be fabricated through the support body 21. As shown in FIG. 4, in an embodiment the support body 21 is formed as an integral piece. Alternatively, as shown in FIG. 5, the support body 21 may come in two pieces secured together. The support body 21 may comprise a first piece 22 and a second piece 23. The first piece 22 may be bonded to the second piece 23 to form the support body 21. A bond layer may be provided between the first piece 22 and the second piece 23.

In an embodiment the vent passage 63 is provided at a bond layer between the first piece 22 and the second piece 23. This may make it easier to manufacture the vent passage 63.

However, it is not essential for the vent passage 63 to be provided. In an alternative embodiment the chamber 62 forms a closed/compressed gas pocket. The chamber 62 may be embodied as a pocket of a thin layer of gas, e.g. air. By omitting the vent passage 63, the thermal conditioning system may be easier to manufacture.

As shown in FIG. 4, in an embodiment the thermal conditioning system comprises a seal configured to seal an outlet of the supply connection 50 from the chamber 62 and/or an environment external to the support body 21. For example, FIG. 4 shows a first seal element 53 above the outlet (i.e. where the conditioning fluid flows from the supply connection 50 into the conditioning channel 61). The first seal element 53 may be between the outlet and the chamber 62. The first seal element 53 is configured to seal an outlet of the supply connection 50 from the chamber 62 and the environment external to the support body 21. In an embodiment the first seal element 53 is an O-ring. As shown in FIG. 4, in an embodiment the first seal element 53 is arranged in a plane substantially perpendicular to the first direction.

FIG. 4 shows a second seal element 56 below the outlet. The seal comprises the second seal element 56 between the outlet and an opening of the support body 21 into which the supply connection 50 is inserted. The second seal element 56 is configured to seal the outlet of the supply connection 50 from the environment external to the support body 21. In an embodiment the second seal element 56 is an O-ring. As shown in FIG. 4, in an embodiment the second seal element 56 is arranged in a plane substantially perpendicular to the first direction. In an embodiment the two sealing elements 53, 56 are arranged substantially perpendicular to the first direction and positioned on each side of the conditioning channel 61 that is in the second direction. In an embodiment the two sealing elements 53, 56 are configured such that the total of the fluid forces on the support body 21 in the first direction is substantially zero.

As shown in FIG. 4, in an embodiment the supply connection 50 is secured to the support body 21 via at least one seal element 53, 56. In an embodiment the supply connection 50 is secured to the support body 21 via at least two seal elements 53, 56, one on either side of the conditioning channel 61.

FIG. 5 schematically depicts a cross-sectional view of an alternative supply connection 50 for a body of a component of a lithographic apparatus. The arrangement illustrated in FIG. 5 and described below may be applied to the lithographic apparatus described above and illustrated in FIG. 1. In FIG. 5, the body to which the supply connection 50 is applied is a support body 21 of a substrate support 20. The support body 21 may be of the type shown in FIG. 2, for example. The supply connection 50 and its application to the body is described below in the context of the body being such a support body 21. The supply connection 50 may additionally or alternatively be applied to one or more other bodies of components of a lithographic apparatus such as the reflector 200 shown in FIG. 3, for example.

As shown in FIG. 5, in an embodiment the supply connection 50 comprises a first end portion 52 and a conduit portion 51. The first end portion 52 and the conduit portion 51 are independently secured to the support body 21, such that the first end portion 52 is fixed relative to the conduit portion 51 only via the support body 21. There is substantially no direct force between the conduit portion 51 and the first end portion 52.

An embodiment of the invention is expected to improve the reliability of manufacturing the thermal conditioning system. As shown in FIG. 5, the pieces 22, 23 of the support body 21 may comprise holes into which the supply connection 50 fits. It is possible that there may be some unintended misalignment between these holes. By providing that the first end portion 52 and the conduit portion 51 are not directly fixed to each other (e.g. not formed integrally), there is a greater tolerance for the misalignment of the holes in the support body 21.

For example, as shown in FIG. 5, in an embodiment the first end portion 52 is secured to the support body 21 (e.g. to the first piece 22 of the support body 21) via a first seal element 53. In an embodiment the seal element 53 is an O-ring. In an embodiment the conduit portion 51 is secured to the support body 21 (e.g. to the second piece 23 of the support body 21) via a second seal element 56. In an embodiment the seal element 56 is an O-ring. The first end portion 52 is not directly connected to the conduit portion 51. The position of the first end portion 52 relative to the conduit portion 51 is fixed via the first piece 22 and the second piece 23 of the support body 21.

It is not essential for the support body 21 to come in two pieces. In an alternative embodiment the support body 21 is formed as a single layer instead of as multiple layers.

As shown in FIG. 5, in an embodiment the supply connection 50 comprises a second end portion 55. The second end portion 55 is configured to be secured to a fluid supply such as the fluid manifold 70 for supplying the conditioning fluid. For example, as shown in FIG. 5, in an embodiment the second end portion 55 is secured to the fluid manifold 70 via a third seal element 57. In an embodiment the third seal element 57 is an O-ring.

As shown in FIG. 5, in an embodiment the supply connection 50 comprises a mechanical connector 54. The mechanical connector 54 is configured to mechanically connect the first end portion 52 to the second end portion 55 through the conduit portion 51. The mechanical connector 54 extends through the conduit portion 51 without contacting the conduit portion 51. The conduit portion 51 surrounds the mechanical connector 54. The mechanical connector 54 is configured to mechanically connect the ends of the supply connection 50 so as to transfer forces between them. This allows for a balancing of the forces at either end of the supply connection 50. This reduces the overall force on the support body 21 due to the supply connection 50 and flow of conditioning fluid.

There may be some misalignment of the holes into which the first end portion 52 and the second end portion 55 fit. The mechanical connector 54 is configured to flex laterally to allow for any such misalignment.

As shown in FIG. 5, in an embodiment the mechanical connector 54 is directly secured to the first end portion 52. The mechanical connector 54 may be formed integrally with the first end portion 52.

As shown in FIG. 5, in an embodiment the mechanical connector 54 forms a tube. The tube is configured to fluidly connect the chamber 62 to a volume 73 beyond the second end portion 55. The volume may be a pocket of gas, e.g. air. This allows the chamber 62 to be vented without requiring the vent passage 63 shown in FIG. 4. The tube is configured to equalize the pressure at either end of the conduit portion 51 of the supply connection 50.

As shown in FIG. 5, in an embodiment the chamber 62 is fluidly connected to an environment external to the support body 21 via the tube formed by the mechanical connector 54. As shown in FIG. 5, in an embodiment a venting hole 74 is provided for fluidly connecting the volume 73 to the ambient environment. The mechanical connector 54 forms a venting tube through the supply connection 50 via the bottom venting hole 74.

As shown in FIG. 5, a vent passage 63 such as is shown in FIG. 4 may be omitted, while allowing venting of the chamber 62. An embodiment of the invention is expected to reduce the complexity of the design of the support body 21. In particular there is no need to fabricate an additional hole/channel inside the support body 21.

The support body 21 can be formed from any material known in the art. For example, the support body 21 may be formed from SiSiC, SiC, AlN, Zerodur™, Cordierite, or some other suitable ceramic or glass-ceramic material. The support body 21 may be coated. The type of coating is not particularly limited, and may be any coating known to a person skilled in the art to be suitable for the application. For example, the support body 21 may be coated with diamond, or diamond-like carbon (DLC).

The invention may be embodied as a method of thermal conditioning. In an embodiment the method comprises entering a conditioning fluid into a body such as the support body 21 through the supply connection 50 in a first direction. In an embodiment the method comprises flowing the conditioning fluid through the supply connection 50 and into the conditioning channel 61 of the support body 21 in a second direction different from the first direction, thereby supplying the conditioning fluid to the conditioning channel 61 of the support body 21. In an embodiment the method comprises flowing the conditioning fluid through the conditioning channel 61 so as to thermally condition the support body 21 and/or a component such as a substrate W supported by or supporting the support body 21. In an embodiment a force applied by the supply connection 50 to the support body 21 is reduced by a chamber 62 of the support body 21 adjacent to the supply connection 50 in the first direction.

In an embodiment the method comprises venting the chamber 62 to/from an environment external to the support body 21.

In an embodiment the method comprises at least partially inserting the supply connection 50 into the support body 21 in the first direction.

In an embodiment the method comprises securing the supply connection 50 to the support body 21.

In an embodiment the securing comprises securing a first end portion 52 of the supply connection 50 to the support body 21, and independently securing a conduit portion 51 to the support body 21, such that the first end portion 52 is fixed relative to the conduit portion 51 only via the support body 21.

In an embodiment the method comprises securing a first piece (or body portion) 22 to a second piece (or body portion) 23 so as to form the support body 21, wherein the first end portion 52 is secured to the first piece 22 and the conduit portion 51 is secured to the second piece 23.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate support WT, etc.,

Specifically, the lithographic apparatus may comprise the projection system PS configured to project the radiation beam B towards the region of the surface of a substrate W. The lithographic apparatus may further comprise the substrate support as described in any of the above embodiments and variations.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A thermal conditioning system for a lithographic apparatus, the thermal conditioning system comprising:
a body comprising a conditioning channel for flow of a conditioning fluid for thermally conditioning the body and/or a component supported by or supporting the body; and
a supply connection configured to supply the conditioning fluid to the conditioning channel of the body, the supply connection shaped such that the conditioning fluid enters the body in a first direction and flows into the conditioning channel in a second direction different from the first direction,
wherein the body comprises a chamber adjacent to the supply connection in the first direction and configured to at least reduce a force applied by the supply connection to the body.

2. The thermal conditioning system of claim 1, wherein the body is substantially plate shaped, and an angle between the second direction and a plane parallel to the plate shape is less than an angle between the second direction and a normal to the plane.

3. The thermal conditioning system of claim 1, wherein the supply connection is shaped such that conditioning fluid flowing substantially straight through the supply connection so as to enter the body along the first direction encounters an inner surface of the supply connection, and/or wherein the chamber is fluidly connectable to an environment external to the body, and/or wherein the supply connection comprises a first end portion and a conduit portion independently secured to the body, such that the first end portion is fixed relative to the conduit portion only via the body.

4. The thermal conditioning system of claim 3, wherein the supply connection comprises a second end portion configured to be secured to a fluid supply for supplying the conditioning fluid.

5. The thermal conditioning system of claim 1, wherein the body comprises a vent passage configured to fluidly connect the chamber to an environment external to the body, and/or comprising a seal configured to seal an outlet of the supply connection from the chamber and/or from an environment external to the body.

6. The thermal conditioning system of claim 5, comprising the seal and wherein the seal comprises a first seal element between the outlet and the chamber.

7. The thermal conditioning system of claim 5, comprising the seal and wherein the seal comprises a second seal element between the outlet and an opening of the body into which the supply connection is inserted.

8. The thermal conditioning system of claim 1, wherein the body is a substrate support configured to support a substrate or wherein the body is an optical reflector or a reflector support configured to support an optical reflector.

9. A lithographic apparatus including the thermal conditioning system according to claim 1.

10. A method comprising:
entering a conditioning fluid into a body through a supply connection in a first direction;
flowing the conditioning fluid through the supply connection and into a conditioning channel of the body in a second direction different from the first direction; and
flowing the conditioning fluid through the conditioning channel of the body so as to thermally condition the body and/or a component supported by or supporting the body,
wherein a force applied by the supply connection to the body is at least reduced by a chamber of the body adjacent to the supply connection in the first direction.

11. The method of claim 10, further comprising venting the chamber to/from an environment external to the body and/or at least partially inserting the supply connection into the body in the first direction.

12. The method of claim 11, further comprising securing the supply connection to the body.

13. The method of claim 12, wherein the securing comprises securing a first end portion of the supply connection to the body, and independently securing a conduit portion to the body, such that the first end portion is fixed relative to the conduit portion only via the body.

14. The method of claim 13, further comprising securing a first body portion to a second body portion so as to form the body, wherein the first end portion is secured to the first body portion and the conduit portion is secured to the second body portion.

15. A method of manufacturing a device including the method according to claim 10.

16. A fluid system comprising:
a body comprising a channel for flow of a fluid through at least part of the body; and
a supply connection configured to supply the fluid to the channel of the body, the supply connection shaped so as to change a direction of flow of the fluid passing through the supply connection from a first direction to flow into the channel in a second direction different from the first direction,
wherein the body comprises a chamber adjacent to the supply connection in the first direction and configured to at least reduce a force applied by the supply connection to the body.

17. The system of claim 16, wherein the supply connection is shaped such that fluid flowing substantially straight through the supply connection so as to enter the body along the first direction encounters an inner surface of the supply connection.

18. The system of claim 16, wherein the chamber is fluidly connectable to an environment external to the body.

19. The system of claim 16, wherein the supply connection comprises a first end portion and a conduit portion independently secured to the body, such that the first end portion is fixed relative to the conduit portion only via the body.

20. The system of claim 16, wherein the body comprises a vent passage configured to fluidly connect the chamber to an environment external to the body, and/or comprising a seal configured to seal an outlet of the supply connection from the chamber and/or from an environment external to the body.
